(19) United States
(12) Patent Application Publication
(10) Pub. No.: US 2017/0192542 A1
(43) Pub. Date: Jul. 6, 2017

(54) TRACK PAD SEMICONDUCTOR PACKAGE USING COMPRESSION MOLDING AND METHOD FOR MANUFACTURING THE SAME

(71) Applicant: HANA MICRON INC., Asan-si (KR)

(72) Inventor: Hyun Joo KIM, Yongin-si (KR)

(73) Assignee: HANA MICRON INC., Asan-si (KR)

(21) Appl. No.: 15/397,318

(22) Filed: Jan. 3, 2017

(30) Foreign Application Priority Data
Jan. 6, 2016 (KR) 10-2016-0001659

(51) Int. Cl. G06F 3/0354; H01L 21/78; G06K 9/00; H01L 21/56; H01L 23/00; H01L 23/29

(52) U.S. Cl. CPC G06F 3/03547; H01L 24/43; H01L 24/45; H01L 23/291; G06K 9/00087; G06K 9/00053; H01L 21/56; H01L 21/78; H01L 2224/48091

(57) ABSTRACT

Provided is a method for manufacturing a track pad semiconductor package using compression molding, including: preparing an original glass assembly; attaching each track pad element on an original PCB; bonding a wire between the original PCB and the track pad element; bonding the original glass assembly onto the track pad element using compression molding of the EMC; and singulating the compression-molded original PCB. According to the configuration of the present disclosure, fingerprint recognizing sensitivity is significantly improved while minimizing the entire thickness of the package.

### CROSS-REFERENCE TO RELATED APPLICATIONS

This application claims the priority of Korean Patent Application No. 10-2016-0001659 filed on Jan. 6, 2016, in the Korean Intellectual Property Office, the disclosure of which is incorporated herein by reference.

### BACKGROUND

Field

The present disclosure relates to a method for manufacturing a track pad semiconductor package for fingerprint recognition of a smart device, and more particularly, to a method for manufacturing a track pad semiconductor package for fingerprint recognition in which an original PCB on which a fingerprint recognizing track pad element is mounted is disposed on an upper mold by air suction to be faced down and a cover glass is disposed on a lower mold by air suction to be faced up, when a powder type EMC is injected onto the cover glass and the upper and lower molds are pressurized in a liquid flowing state, the EMC is extruded between the track pad element and the glass so that the glass and the track pad element are coupled to each other with a minimum clearance therebetween without using a separate adhesive.

Further, the present disclosure further relates to a track pad semiconductor package element for fingerprint recognition which is manufactured by compression molding and more particularly, to a track pad semiconductor package for fingerprint recognition in which a step is equipped on one side of a track pad element by a trench and a conductive wire is bonded to the step so that the thickness of an EMC mold is reduced to a minimum required to bond the track pad element and a glass to each other.

Description of the Related Art

Generally, a fingerprint recognizing sensor is a sensor which senses a fingerprint of a human and is being widely used as a means for enhancing a security of portable electronic equipment such as a mobile phone or a tablet PC in recent years. That is, user registration or an authentication process is performed through a fingerprint recognizing sensor so as to protect data stored in the portable electronic equipment and avoid security incidents in advance.

It is a recent trend to request the fingerprint recognizing sensor as a general input means. For example, in the smart device, a navigation function which manipulates a pointer such as a cursor is integrated in the fingerprint recognizing sensor. In addition, a switching function which receives information from a user is integrated in the fingerprint recognizing sensor. Therefore, it is considered that the fingerprint recognizing sensor includes various sensor functions in addition to a fingerprint recognizing function.

Referring to FIG. 1, a track pad package 10 of the related art includes a PCB 12, a track pad element 16 which is laminated on the PCB 12 using an adhesive 14, a conductive wire 18 which electrically connects the PCB 12 and the track pad element 16, an EMC mold 20 which protects the track pad element 16 and the conductive wire 18, and a glass assembly 30 which is attached to the EMC mold 20 using a bonding tape 30c and has a color coating layer 30b formed on a cover glass 30a.

A clearance h1 between an upper surface of the track pad element 16 and an upper surface of the EMC mold 20 is approximately 150 um, which becomes a cause of lowering a sensitivity of a sensor. Therefore, the clearance needs to be minimized by removing the thickness of the EMC mold 20 which is applied on the track pad element 16.

However, there is a limitation to minimize the clearance due to the conductive wire 18 which connects the PCB 12 and the track pad element 16 and the entire thickness of the track pad semiconductor package cannot be reduced any more due to the clearance.

### RELATED ART DOCUMENT

### Patent Document

Patent Document 1: Korean Unexamined Patent Application Publication No. 10-2015-0080812

### SUMMARY

An object to be achieved by the present disclosure is to provide a track pad semiconductor package using compression molding and a method for manufacturing the same which are capable of minimizing the entire thickness of a track pad semiconductor package.

Another object of the present disclosure is to provide a track pad semiconductor package using compression molding and a method for manufacturing the same which minimize a thickness of the EMC interposed between the track pad element and the glass required to bond the track pad and the glass.

According to an aspect of the present disclosure, there is provided a track pad semiconductor package in which a fingerprint recognizing track pad element of a smart device is mounted on a PCB, a cover glass for protection is provided on the track pad element, and an EMC mold is provided, in which a powder type EMC is compression-molded between the track pad element and a glass assembly and the track pad element and the glass assembly are bonded to each other while hardening the EMC mold in a liquid flowing state.

According to another aspect of the present disclosure, a method for manufacturing a track pad semiconductor package includes preparing an original glass assembly; attaching each track pad element on an original PCB; wire bonding between the original PCB and the track pad element; bonding the original glass assembly onto the track pad element using compression molding of the EMC; and singulating the compression-molded original PCB.

According to still another aspect of the present disclosure, a track pad semiconductor package includes a PCB, a track pad element laminated on the PCB; a conductive wire which connects the PCB and the track pad element; an EMC mold which is molded on the track pad element by compression molding (C-molding); and a glass assembly which is bonded onto the EMC mold by the compression molding.

As described above, the following advantages are expected by the configuration of the present disclosure:

First, since the glass is attached to a sensor unit with a shortest distance therefrom, a clearance is reduced and a sensibility is significantly improved.

Second, when a compression molding process is used, the glass is coupled to the EMC without using a separate bonding tape (DAF). When a color bonding tape is used, a color coating process may be omitted.

Third, a thickness of an EMC mold required to bond the conductive wire is removed due to a trench which is formed on one surface of the track pad, so that it is useful to reduce the thickness of the package to a minimum.

Fourth, since a powder type EMC is used to perform upper and lower compression molding between an original PCB and an original glass, it is economical to manufacture a plurality of packages at one time.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view illustrating a configuration of a track pad semiconductor package of the related art;

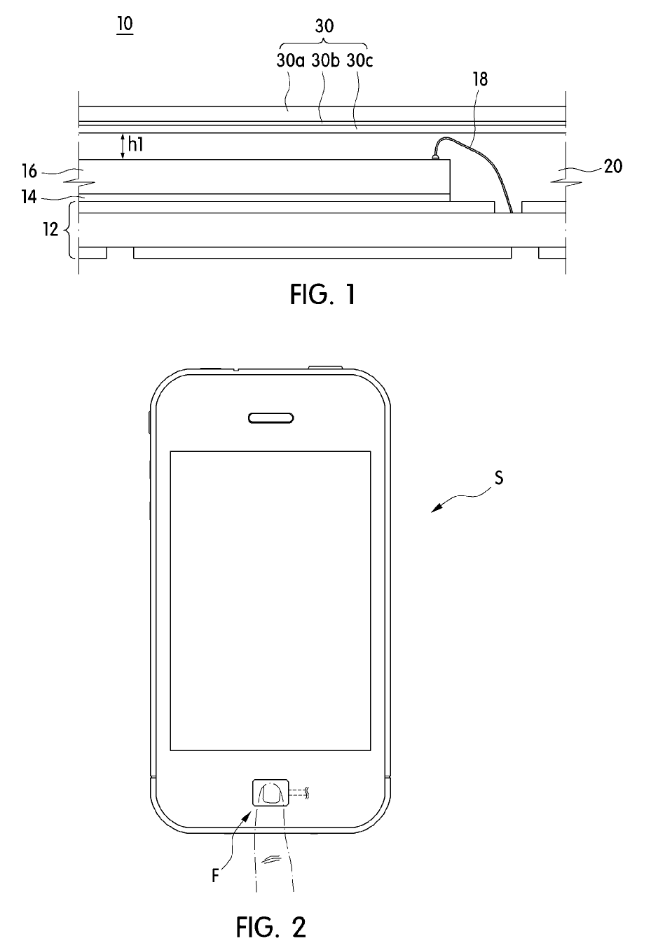

FIG. 2 is a plan view illustrating a configuration of a fingerprint recognizing sensor module in a smart device according to the present disclosure;

FIG. 3 is a cross-sectional view illustrating a configuration of a track pad semiconductor package using compression molding according to the present disclosure;

FIGS. 4A to 4F are cross-sectional views illustrating manufacturing processes of the track pad semiconductor package of FIG. 3; and

FIG. 5 is a flowchart illustrating a manufacturing process of a track pad semiconductor package using compression molding according to the present disclosure.

### DETAILED DESCRIPTION OF THE PREFERRED EMBODIMENT

Advantages and characteristics of the present invention and a method of achieving the advantages and characteristics will be clear by referring to exemplary embodiments described below in detail together with the accompanying drawings. However, the present disclosure is not limited to the following exemplary embodiments but may be implemented in various different forms. The exemplary embodiments are provided only to complete disclosure of the present disclosure and to fully provide a person having ordinary skill in the art to which the present disclosure pertains with the category of the disclosure, and the present disclosure will be defined by the appended claims. In the drawings, a size and a relative size of a layer or an area may be exaggerated for clarity of description. Like reference numerals generally denote like elements throughout the specification.

Exemplary embodiments described in this specification may be described with reference to cross-sectional views and/or plan views which are ideal schematic views of the present disclosure. Therefore, a shape of the exemplary view may be modified by a manufacturing technology and/or an allowable error. Accordingly, exemplary embodiments of the present disclosure are not limited to specific illustrated types but may include modified types which are generated in accordance with the manufacturing process. Therefore, regions illustrated in the drawings have properties. Shapes of the regions illustrated in the drawings are provided to illustrate a specific shape of a region of an element, but not limit the scope of the present disclosure.

Hereinafter, an exemplary embodiment of a track pad semiconductor package using compression molding of the present disclosure with the above-described configuration will be described in detail with reference to the accompanying drawings.

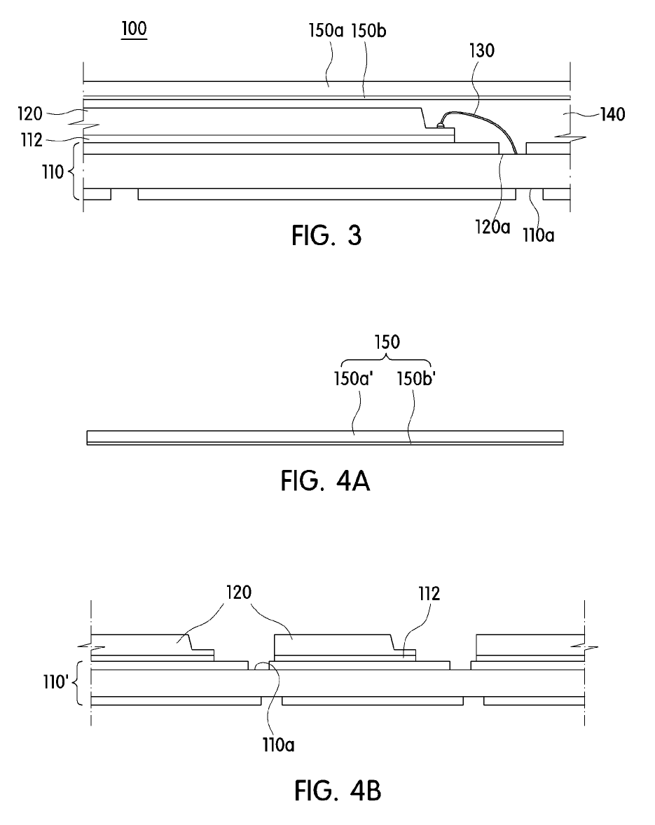

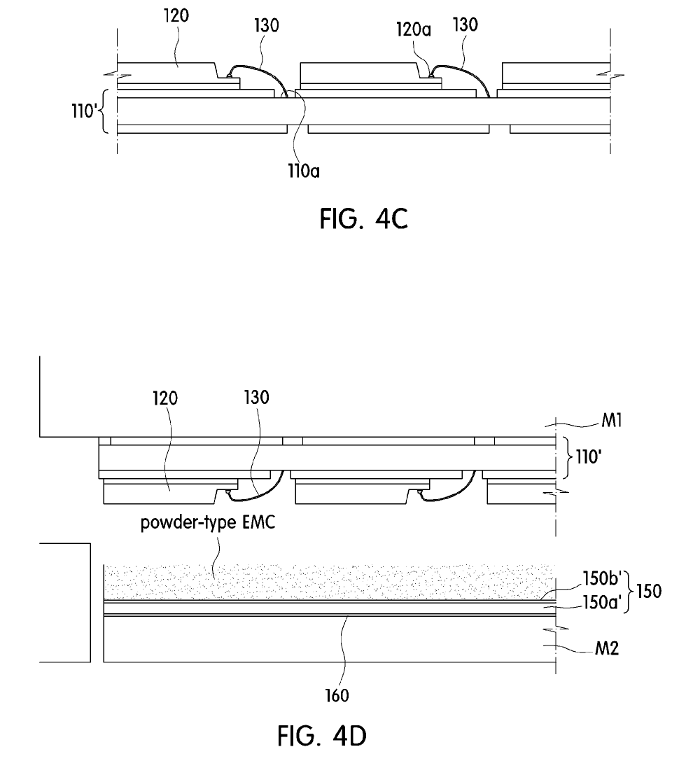

FIG. 2 illustrates a plan view of a fingerprint recognizing sensor module of a smart device according to the present disclosure and FIG. 3 illustrates a cross-sectional view of a configuration of a track pad semiconductor package using compression molding which is applied to the fingerprint recognizing sensor module of FIG. 2.

Referring to FIG. 2, a fingerprint recognizing sensor module F may be mounted on a bottom button of a front surface of a smart device S. The fingerprint recognizing sensor module F includes a fingerprint recognizing track pad package 100 and a connecting unit (for example, a flexible PCB cable) which supports the package 100 and electrically connects the package 100 to a main body of the smart device S. Specifically, a home dome button may be provided at a lower portion of the fingerprint recognizing track pad package 100 according to a specification of the smart device S.

The smart device S may include all types of portable electronic devices such as a smart phone, a personal digital assistant (PDA), a handheld PC, a cell phone, and other smart device having a similar function.

The fingerprint recognizing track pad semiconductor package of the present disclosure may be used for a fingerprint recognizing sensor module F in the above-described smart device S.

Referring to FIG. 3, the track pad semiconductor package 100 using compression molding of the present disclosure includes a PCB 110, a track pad element 120 which is laminated on the PCB 110 using an adhesive 112, a conductive wire 130 which electrically connects the PCB 110 and the track pad element 120, an EMC mold 140 which covers the track pad element 120, and a glass assembly 150 which is attached to the EMC mold 140 without using a separate adhesive.

The PCB 110 may include both a soft board and a hard board. In the PCB 110, a wiring pattern (not denoted by a reference numeral) is formed to electrically connect the track pad element 120 to an external device and specifically, a bump, and the like, may be formed below the PCB 110 by a surface mounting technique (SMT). The PCB 110 may be locked with the above-described connecting unit of the module F or may serve as a connecting unit.

Even though not illustrated in the drawing, the track pad element 120 may include a sensor unit which generates a sensor signal and an ASIC which processes the sensor signal. The sensor unit includes a transmitter which transmits an RF signal and a receiver which receives the sensor signal. Therefore, the ASIC may be mounted in the track pad element 120 and the sensor unit may be mounted above the track pad element 120. The track pad element 120 is not specifically limited as a fingerprint recognizing semiconductor element.

The track pad element 120 may be provided in the form of a trench semiconductor chip. A step (not denoted by a reference numeral) is formed at one side of the track pad element 120 by a trench so that the conductive wire 130 is seated to be bonded thereto and a chip pad 120a is formed in the step. Therefore, one end of the conductive wire 130 is connected to the chip pad 120a and the glass assembly 150 does not need to avoid the conductive wire 130.

According to the fingerprint recognizing track pad semiconductor package 100 of the present disclosure, static electricity according to a shape of a fingerprint is sensed and the fingerprint authentication is performed using the static electricity as an input signal. For example, fingers have fingerprints formed by combinations of ridges and valleys and shape information of the ridges and the valleys is output using electrostatic capacitance difference due to unevenness (a height difference of the ridges and valleys). The shape information is formed to be an image or compared with reference information to perform fingerprint authentication.

The adhesive 112 includes an anisotropic conductive film (ACF) or an anisotropic conductive adhesive (ACA). Alternatively, a non-conductive film (NCA or NCF) may be used. For example, the track pad element 120 may be electrically connected onto the PCB 110 by flip-chip bonding. In this case, the anisotropic conductive film or adhesive may connect the flip chip bonding. When the track pad element 120 is electrically connected by the wire bonding, the track pad element 120 may be connected by the non-conductive film NCA or NCF.

The conductive wire 130 electrically connects a substrate pad 110a on an upper surface of the PCB 110 and the chip pad 120a on the track pad element 120. As described above, since the chip pad 120a is formed in the trench, the chip pad is freely bonded regardless of the thickness of the track pad element 120.

The glass assembly 150 includes a cover glass 150a and a color coating layer 150b which is coated with color on one surface of the cover glass 150a. As described above, a separate adhesive or bonding tape having a bonding property is not included between the color coating layer 150a and the EMC mold 140. The color coating layer 140a may include a colored layer and a protection film. On the colored layer, a color film is attached ora color ink is printed. Various color implementations may be allowed by forming the color layer as described above. The glass assembly 150 may include sapphire or tempered cover glass. If necessary, an unevenness treatment may be performed on the upper surface of the cover glass 150a for a touch feeling. The cover glass 150a may have the substantially same area as the color coating layer 140b. When the track pad semiconductor package 100 of the present disclosure is used for fingerprint authentication of a smart device (smart phone), the cover glass 150a may have a circular shape or an oval shape.

In the present disclosure, there is a trench seating unit, so that there is no need to specifically interpose the EMC mold 140 between the track pad element 120 and the glass assembly 150. However, since the glass assembly 150 is coupled to the track pad semiconductor package 100 without using the bonding tape DAF, the EMC mold 140 may be interposed between the track pad element 120 and the glass assembly 150. However, the thickness thereof may be freely determined within a range which does not interrupt the sensitivity.

As described above, the EMC mold 140 is required to protect the conductive wire 130 and the conductive wire 130 and the chip pad 120a to which one end of the conductive wire 130 is connected and the substrate pad 110a to which the other end of the conductive wire 130 is connected need to be surely covered.

The track pad semiconductor package 100 of the present disclosure has an advantage in that even though the glass assembly 150 is provided over the entire area of the package, the thickness of the entire package is not increased. That is, the glass assembly 150 may cover not only a sensing area but also a non-sensing area. Therefore, the glass assembly covers not only the sensor unit of the track pad element 120 but also the ASIC and is widely provided even in an area of the conductive wire 130 which is not related to the sensing function so that integrity of the package is enhanced.

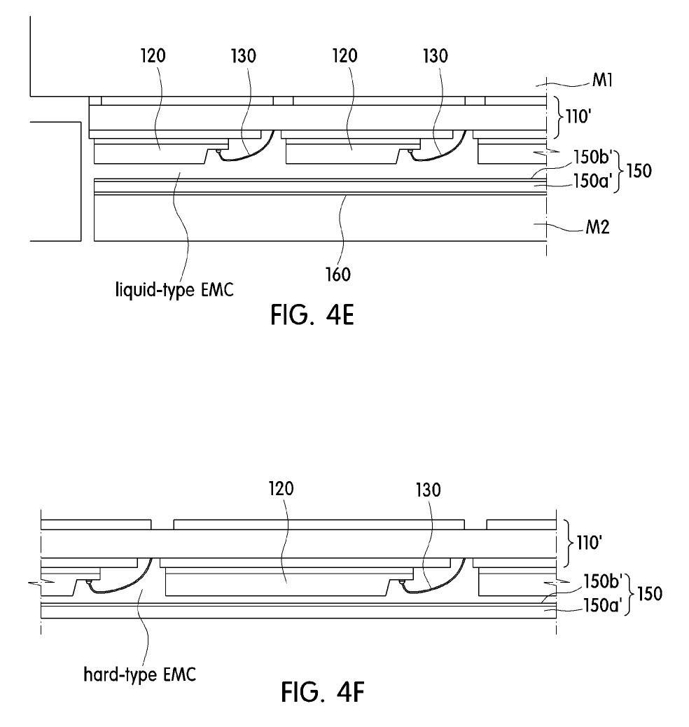

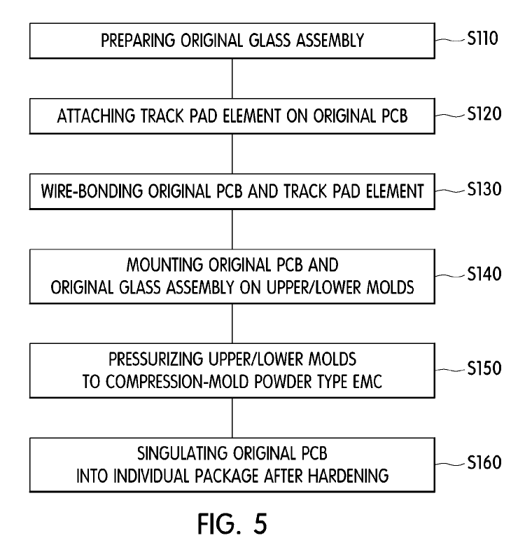

Hereinafter, a manufacturing method of a track pad semiconductor package of the present disclosure will be described with reference to FIGS. 4A to 5.

### Step S110 of Preparing Original Glass Assembly

Referring to FIG. 4A, an original glass assembly 150a′ to be coated with color is prepared. An original color coating layer 150b′ which is coated with color is included on one surface of the original glass assembly 150a′. A bonding tape may be omitted in the original glass assembly 150a′ of the present disclosure.

Further, the original glass assembly is not divided into individual glass assemblies by a singulation process. For example, a size of the original glass assembly 150a′ is 240 mm×95 mm or 240 mm×75 mm.

### Step S120 of Attaching Track Pad Element Onto Original PCB

Referring to FIG. 4B, a track pad element 120 is mounted on an original PCB 110′ using an adhesive 102. On the original PCB 110′, a substrate pad 110a is formed and the track pad element 120 is mounted so as not to cover the substrate pad 110a. When the track pad element 120 is connected by wire bonding, the track pad element 120 is attached using a non-conductive adhesive 112 and when the track pad element 120 is connected by flip chip bonding, an anisotropic adhesive 112 may be used.

### Step S130 of Wire Bonding Original PCB and Each Track Pad Element

Referring to FIG. 4C, a bonding process which connects one end of the conductive wire 130 to the chip pad 120a and the other end of the conductive wire 130 to the substrate pad 110a is performed. As described above, the present disclosure has an advantage in that the EMC mold 140 is coupled without using the bonding tape DAF, but using compression molding (C-molding) EMC mold.

### Step S140 of Mounting Original PCB and Original Glass Assembly on Upper/Lower Molds

Referring to FIG. 4D, the upper mold M1 fixes the original PCB 110′ by air suction and the lower mold M2 fixes the original glass assembly 150a′ by air suction. For example, the original PCB 110′ on which the track pad element 120 is assembled by an attaching process is mounted on the upper mold M1 and the original glass assembly 150′ is mounted on the lower mold M2.

In this case, a release film 160 is prepared to laminate the original glass assembly 150a′ on the lower mold M2. The release film 160 may use a polyester film (FET) having a silicon composition and an antistatic function on at least one surface to protect the original glass assembly 150a′.

### Step S150 of Compression-Molding EMC by Pressuring Upper/Lower Molds

Referring to FIG. 4E, the original PCB 110′ is disposed on the upper mold M1 by air suction to be faced down and the original glass assembly 150a′ is disposed on the lower mold M2 by air suction to be faced up, to form a cavity. Powder type EMC is injected onto the original glass assembly using the cavity. When the powder type EMC starts to be heated and pressurized while suppressing the flowing of the powder type EMC, the powder type EMC is gradually changed to a liquid type. The EMC is hardened between the track pad element 120 and the original glass assembly 150′ so that the glass and the track pad are coupled to each other without using a separate adhesive.

### Step S160 of Singulating Compression-Molded Original PCB Into Package

Referring to FIG. 4F, when the liquid type EMC is hardened, the original package is separated from the upper/lower molds M1 and M2. Thereafter, the original package is cut into unit packages.

The EMC mold 140 is formed by a compression molding process which will be described below. Therefore, the EMC mold 140 is finished by the final process and the glass assembly 150 is designed to cover the entire upper surface of the EMC mold 140.

Most of all, a separate bonding tape DAF for mounting the glass assembly 150 on the EMC mold 140 may be omitted. For example, the glass assembly 150 and the powder type EMC are in directly contact with each other using the compression molding (C-molding) and the liquid flowing state EMC is coupled to the glass assembly 150 before being hardened, so that a separate adhesive may be omitted and a bonding property is further enhanced.

As described above, it is understood that the present disclosure has a technical spirit in which the original PCB is disposed on the upper mold using air suction to be faced down and the original glass is disposed on the lower mold to be faced up and the powder type EMC is injected onto the original glass and then heated and pressurized to harden the liquid state EMC to manufacture a package. Those skilled in the art may make various changes within a basic technical spirit of the present disclosure.

What is claimed is:

1. A track pad semiconductor package in which a fingerprint recognizing track pad element of a smart device is mounted on a PCB, a cover glass for protection is provided on the track pad element, and an EMC mold is provided, wherein a powder type EMC is compression-molded between the track pad element and a glass assembly and the track pad element and the glass assembly are bonded to each other while hardening the EMC mold in a liquid flowing state.

2. The track pad semiconductor package of claim 1, wherein a step is equipped on one side of the track pad element by a trench and a conductive wire is bonded to the step so that a thickness of an EMC mold is reduced to a minimum required to bond the track pad element and the glass assembly to each other.

3. A method for manufacturing a track pad semiconductor package, the method comprising:
preparing an original glass assembly;
attaching each track pad element on an original PCB;
wire bonding between the original PCB and the track pad element;
bonding the original glass assembly onto the track pad element using compression molding of the EMC; and
singulating the compression-molded original PCB.

4. The method of claim 3, wherein the bonding of the original glass assembly using compression molding of the EMC includes:
mounting the original PCB on a bottom surface of an upper mold by air suction and mounting the original glass assembly on a top surface of a lower mold by air suction; and
compression-processing the upper and lower molds while injecting a powder type EMC between the original PCB and the original glass assembly.

5. The method of claim 4, wherein the original glass assembly is mounted on the top surface of the lower mold using a PET release film having a silicon composition and an antistatic function.

6. The method of claim 4, wherein the preparing of an original glass assembly is finished by applying an original color coating layer on the original glass,
in the wire bonding, one end of a conductive wire is connected to a chip pad, the chip pad is formed in a trench at one side of the track pad element and the one end of the conductive wire is connected to the chip pad in the trench, and
in the attaching of the track pad element, the track pad element is bonded using a non-conductive adhesive.

7. A track pad semiconductor package, comprising:
a PCB;
a track pad element laminated on the PCB;
a conductive wire which connects the PCB and the track pad element;
an EMC mold which is molded on the track pad element by compression molding (C-molding); and
a glass assembly which is bonded onto the EMC mold by the compression molding.

8. The track pad semiconductor package of claim 7, wherein the track pad element includes a semiconductor chip including a trench at one side, the conductive wire electrically connects a substrate pad on the PCB and a chip pad on the track pad element, and the chip pad is formed in the trench.

9. The track pad semiconductor package of claim 8, further comprising:
a step in which a bonding wire is seated by the trench,
wherein the conductive wire is connected to the step.

10. The track pad semiconductor package of claim 8, wherein the glass assembly includes:
a cover glass; and
a color coating layer which is coated on one surface of the cover glass with color,
wherein the EMC mold is directly bonded to the color coating layer.
